(19) United States
(12) Patent Application Publication
(10) Pub. No.: US 2024/0304731 A1
(43) Pub. Date: Sep. 12, 2024

(54) RESISTOR

(71) Applicant: STMicroelectronics International N.V., Geneva (CH)

(72) Inventors: Francois TAILLIET, Fuveau (FR); Marc BATTISTA, Allauch (FR)

(73) Assignee: STMicroelectronics International N.V., Geneva (CH)

(21) Appl. No.: 18/594,210

(22) Filed: Mar. 4, 2024

(30) Foreign Application Priority Data
Mar. 7, 2023 (FR) 2302099

(51) Int. Cl. H01L 29/8605; H01L 27/06

(52) U.S. Cl. CPC H01L 29/8605; H01L 27/0629

(57) ABSTRACT

An electronic device includes first and second diffused resistors in contact with each other to form a PN junction. The device is configured so that a potential difference between the first and second resistors is constant at any point of the PN junction. The PN junction is reverse-biased.

### PRIORITY CLAIM

This application claims the priority benefit of French Application for Patent No. 2302099, filed on Mar. 7, 2023, the content of which is hereby incorporated by reference in its entirety to the maximum extent allowable by law.

### TECHNICAL FIELD

The present disclosure generally concerns electronic devices and, in particular, devices comprising resistors and their control methods.

### BACKGROUND

A resistor is an electronic or electric component having as a main characteristic to oppose a resistance, higher or lower, to the flowing of an electric current. In integrated circuit technology, two categories of resistors are mainly known: polysilicon resistors and diffused or implanted resistors, that is, using dopants of different types (typically P and N) in a semiconductor substrate (typically made of silicon). The present disclosure concerns the second category of resistors (i.e., integrated circuit resistors of the diffused or implanted type).

There is a need in the art to address all or part of the disadvantages of known devices comprising diffused resistors.

### SUMMARY

An embodiment provides an electronic device comprising first and second diffused resistors in contact with each other so as to form a PN junction, the device being configured so that the potential difference between the first and second resistors is constant at any point of the PN junction, the device being configured so that the PN junction is reverse-biased.

Another embodiment provides a method of controlling a device comprising first and second diffused resistors in contact with each other so as to form a PN junction, the potential difference between the first and second resistors being constant at any point of the PN junction, the device being configured so that the PN junction is reverse-biased.

According to an embodiment, each of the first and second diffused resistors is made of doped semiconductor materials, the first and second diffused resistors being doped with opposite conductivity types.

According to an embodiment, the first resistor comprises a first layer buried in a substrate and first wells, the first wells extending from the periphery of the first layer to a first surface of the substrate, the first layer and the first wells being made of a doped semiconductor material of a first conductivity type; and the second resistor comprises a second layer resting on the first layer, the second layer being made of a doped semiconductor material of a second conductivity type.

According to an embodiment, the second resistor comprises a third doped semiconductor layer of a first conductivity type, the third layer being flush with an upper surface of a substrate; and the first resistor comprises a second layer made of a doped semiconductor material of a second conductivity type, the third layer resting on the second layer.

According to an embodiment, the device further comprises a third resistor, the third resistor comprising a first layer buried in the substrate and first wells, the first wells extending from the periphery of the first layer to the first surface of the substrate, the first layer and the first wells being made of a doped semiconductor material of a first conductivity type, the first layer and the first wells delimiting the second layer.

According to an embodiment, the PN junction being the first and the third resistor is configured to be reverse-biased.

According to an embodiment, the first resistor comprises a semiconductor well in a substrate, the semiconductor well being doped with the type opposite to the doping type of the substrate; and the second resistor comprises a third doped semiconductor layer of the type opposite to the doping type of the semiconductor well, the third layer being flush with an upper surface of a substrate.

According to an embodiment, each of the resistors comprises a first end and a second end, each resistor comprising, at the level of the first and second ends, a semiconductor region, more heavily doped than the rest of the resistor, forming a terminal of said resistor.

According to an embodiment, each first and second resistor comprises first and second terminals, the second terminals of the first and second resistors being coupled to a same first node of application of a reference voltage.

According to an embodiment, the device comprises a control circuit configured to supply the potentials on the terminals of the first and second resistors.

According to an embodiment, the control circuit comprises a first transistor series-coupled with the first resistor between a second node of application of a power supply voltage and the first node and a second transistor series-coupled with the second resistor between the second node and the first node, the first and second transistors being diode-mounted.

According to an embodiment, the first transistor has a channel width-to-length ratio equal to the channel width-to-length ratio of the second transistor multiplied by the quotient of the value of the second resistance to the value of the first resistance.

According to an embodiment, the device is configured so that the potential difference between the first and second resistors is zero at any point of the PN junction.

Another embodiment provides a sensor comprising a device such as previously described, the sensor being configured so that a measurement value of the sensor is dependent on the resistance value of the second resistor.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A is a top view of an embodiment of a device comprising a diffused resistor;

FIG. 1B is a cross-section view of the embodiment of FIG. 1A;

FIG. 1C is another cross-section view of the embodiment of FIG. 1A;

FIG. 2A is a top view of another embodiment of a device comprising a diffused resistor;

FIG. 2B is a cross-section view of the embodiment of FIG. 2A;

FIG. 2C is a cross-section view of an embodiment of FIG. 2A;

FIG. 2D is a cross-section view of an embodiment of FIG. 2A;

FIG. 3 shows an example of a circuit comprising a diffused resistor;

FIG. 4 shows another circuit comprising a diffused resistor;

FIG. 5 shows an application of the previously-described embodiments;

FIG. 6A is a top view of another embodiment of a device comprising a diffused resistor;

FIG. 6B is a cross-section view of the embodiment of FIG. 6A; and

FIG. 6C is a cross-section view of an embodiment of FIG. 6A.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

A diffused (or implanted) resistor is formed in a semiconductor substrate, for example made of silicon, of a region generally elongated as a bar of a first conductivity type (P or N) in a well, or the substrate, of a second conductivity type (N or P). Contacting areas at the two ends of the bar define the terminals of the resistor and the well is biased so that the PN junction is reverse-biased.

Among other issues due to the presence of a PN junction and the need to reverse-bias this junction to obtain the resistive effect between the ends of the bar, diffused resistors suffer from a lack of stability of the resistance value with voltage variations. In other words, the resistance value varies along with the voltage applied thereacross.

The described embodiments provide making the value of a diffused (or implanted) resistor voltage-stable, that is, making the resistance value independent from the potentials applied thereacross.

According to the described embodiments, it is provided to bias the region (the well and the buried region) surrounding the resistive bar to compensate for the voltage instability effect. More particularly, it is provided to perform a specific biasing of the region surrounding the resistive bar so that the potential difference, at the level of each point of the interface between the resistive bar and the surrounding region, between the resistive bar and the surrounding region is constant. Accordingly, the voltage gradient which develops in the region surrounding the resistive bar in the longitudinal direction is the same as that which develops in the resistive bar. A potential difference between the resistive bar and the region of opposite type surrounding it which is constant whatever the longitudinal position between the two terminals of the resistive bar is then obtained. This amounts to using the longitudinal resistance (in the direction of the resistive bar) of the region of opposite conductivity type where the resistive bar is located. The variation of the space charge area between the P and N regions in the longitudinal direction of the resistive bar is thus avoided, which makes the resistance value independent from the voltages applied to each of its terminals. In other words, the resistor has a value independent from the potentials thereacross, and thus from the potential difference thereacross.

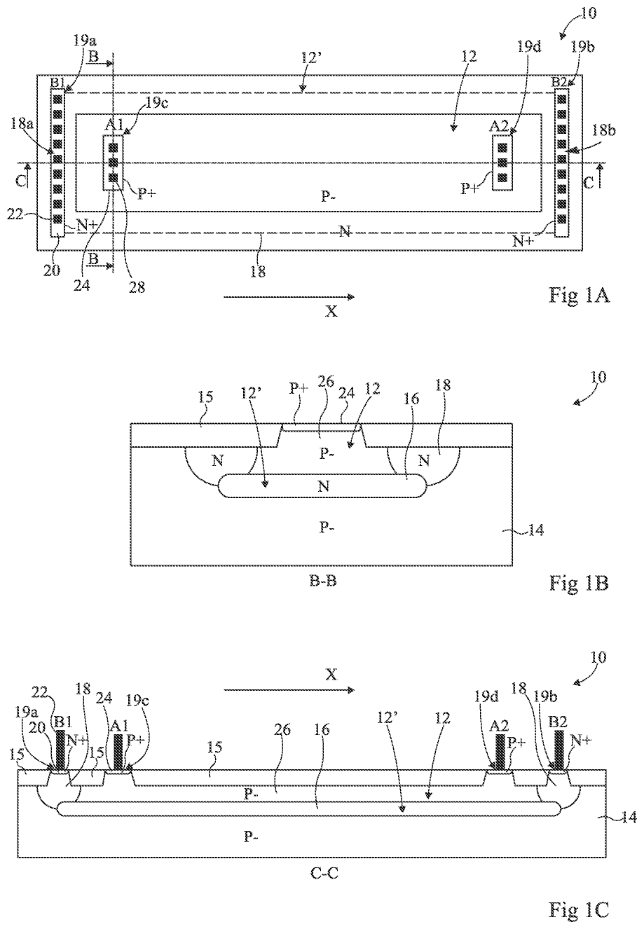

FIG. 1A is a top view of an embodiment of a device 10. FIG. 1B is a cross-section view along line B-B of FIG. 1A. FIG. 1C is a cross-section view along line C-C of FIG. 1A.

Device 10 comprises a substrate 14 (P−) made of a semiconductor material, for example silicon. Substrate 14 is doped, preferably of type P.

Device 10 comprises a well 18 of a conductivity type (N) opposite to that of substrate 14, and a layer 16 or plate, of the same conductivity type (N) as the well, buried in substrate 14 under well 18. Well 18 is, for example, a ring of rectangular shape. Well 18 and buried region 16 delimit, on the front surface side, a region 26 of the substrate of the first conductivity type (P−) forming a resistive bar 12. Well 18 and region 16 form another resistor 12′.

Layer 16 forms, for example, a strip. Layer 16 has, for example, an approximate cuboid shape. Well 18 has the shape of a rectangular ring extending from the front or upper surface of substrate 14 to buried layer 16. Well 18 comprises a first end 18a and a second end 18b. The first and second ends 18a, 18b preferably correspond to the two opposite sides most distant from each other of well 18.

The front surface of the substrate, and thus of device 10, is covered with an insulating layer 15. More precisely, layer 15 covers, preferably partially, an upper surface of substrate 14. Layer 15 is not shown in FIG. 1A for more clarity.

Contacting areas, respectively 20 and 24, are provided in the respective vicinities of the longitudinal ends of well 18 and of region 26. Areas 20 and 24 are respectively N+ and P+ overdoped and contacts 22 and 28 define terminals of electric connection of the respective areas 20 and 24.

An example of a method of forming device 10 comprises the forming, in a semiconductor substrate, for example P-type doped, of well 18. The forming of well 18 is, for example, performed by a step of doping, for example through the openings of a mask located on the upper surface of the substrate. The doping step is such that the wells extend from the upper surface of the substrate. The method then comprises a step of forming of layer 16, for example by implantation of a doping through the openings of another mask located on the upper surface of the substrate. Layer 16 is formed in such a way as to partially extend in wells 18. There accordingly exists an electric continuity between layer 16 and well 18.

Layer 15 is, for example, formed after the forming of well 18. Layer 15 corresponds, for example, to a shallow trench insulation (STI). Layer 15 is, for example, formed by a known shallow trench insulation forming method, for example comprising the forming of a mask exposing the locations of layer 15, the partial etching of the substrate, and the filling of the obtained cavity with an insulating material. Alternatively, the material of layer 15 may be obtained from the material of the substrate, for example by oxidation.

At the level of the ends 18a and 18b of well 18, layer 15 comprises openings 19a and 19b intended for the forming of contacting area 20, flush with the upper surface of the substrate. Preferably, the thickness of area 20 is smaller than the height of layer 15.

Similarly, layer 15 is open in the vicinity of the ends of region 26 for the forming of contacting area 24 and of contacts 28. In other words, layer 15 comprises openings 19c and 19d intended for the forming of contacting area 24, flush with the upper surface of the substrate. Preferably, the thickness of area 24 is smaller than the height of layer 15.

The method of manufacturing device 10 comprises, for example, a step of forming of regions 20, for example by doping of the substrate through openings of another mask located on the upper surface of the substrate. More precisely, the forming of regions 20 comprises the doping of the portion of well 18 flush with the upper surface of the substrate. Preferably, the openings of said mask fully expose openings 19a and 19b.

Well 18 and layer 16 form resistor 12′. Resistor 12′ is a diffused resistor of conductivity type N. The region 20 located in opening 19a forms a first terminal B1 of resistor 12′. The region 20 located in opening 19b forms a second terminal B2 of resistor 12′. Contacts 22 are intended to contact regions 20 to couple resistor 12′ to an electronic circuit. The value of resistor 12′ corresponds to the resistance between terminals B1 and B2. The X direction extending from terminal B1 to terminal B2 corresponds to the main direction of resistor 12′ and is represented by an arrow in FIGS. 1A and 1C.

The method of manufacturing device 10 comprises, for example, a step of forming of regions 24, for example by doping of the substrate through openings of a mask located on the upper surface of the substrate. Preferably, the openings of said mask entirely expose openings 19c and 19d.

Region 26 forms resistor 12. Resistor 12 is a diffused resistor of conductivity type P. The region 24 located in opening 19c forms a first terminal A1 of resistor 12. The region 24 located in opening 19d forms a second terminal A2 of resistor 12. Contacts 28 are intended to contact regions 24 to couple resistor 12 to an electronic circuit. The value of resistor 12 corresponds to the resistance between terminals A1 and A2. The main direction of resistor 12 is the same X direction as the main direction of resistor 12′.

Resistor 12 is thus separated from the rest of P-type doped substrate 14 by resistor 12′. Resistor 12 is separated from the rest of the P-doped substrate by a structure referred to in the art as a triple well formed by well 18 and layer 16. Resistors 12 and 12′ are in contact with each other. More precisely, resistor 12 rests on resistor 12′.

Resistors 12 and 12′ are diffused resistors of opposite conductivity type. Resistors 12 and 12′, and more precisely the interface between resistors 12 and 12′, thus form a PN junction.

Reference VA refers to a voltage applied between the terminals of resistor 12, that is, a potential difference VA1−VA2 between terminals A1 and A2, and VB a voltage applied between the terminals of resistor 12′, that is, a potential difference VB1−VB2 between terminals B1 and B2, voltage differences VB1−VA1 and VB2−VA2 are configured so that the PN junction formed between resistors 12 and 12′ is reverse biased. In other words, at each contact point P between resistor 12 and resistor 12′, the potential VAP of resistor 12 at point P is smaller than or equal to the potential VBP of resistor 12′ at point P. By reverse biased, this would also include the case where the PN junction is zero-biased (in other words, the case where the difference in potential is substantially equal to zero).

The device is further configured so that the difference between the potential of resistor 12′ and the potential of resistor 12 is constant across the entire interface between resistors 12 and 12′ in the X direction. In other words, at any point P of the interface between resistor 12 and resistor 12′, the difference between potential VAP, that is, the potential of resistor 12 at point P, and potential VBP, that is, the potential of resistor 12′ at point P, is substantially equal to a constant value k. Thus, the device is configured so that the following equation applies, in the X direction, across the entire interface between resistor 12 and resistor 12′: VAP−VBP=k. Value k is a constant, positive, or zero value independent from voltage values VA and VB. In particular, this equation applies at the level of terminals A1, A2, B1, B2. Thus, the following equations apply in the device: VA1−VB1=VA2−VB2=k.

For example, value k is strictly a constant, strictly positive, value, and may comprise a value substantially equal to zero. Thus, at any point P of the interface between resistor 12 and resistor 12′, the potential VAP of resistor 12 and the potential VBP of resistor 12′ are substantially equal.

The value of resistor 12 is voltage-stable but not temperature-stable. The above-described embodiment may thus be used as a temperature sensor. Resistor 12 then corresponds to the variable element of the sensor, the variations of the resistance value of resistor 12 being indicative of the variations measured by the sensor, for example indicative of temperature variations. The sensor has, for example, an output having an output signal dependent on the resistance value of resistor 12 generated thereon.

At least one end of each resistors 12, 12′ is coupled and not connected to the associated end of the other resistor 12, 12′. In other words, either terminals A1 and B1 are coupled and not connected to one another, or terminals A2 and B2 are coupled and not connected to one another, or terminals A1 and B1 are coupled and not connected to one another and terminals A2 and B2 are coupled and not connected to one another. By coupled and not connected to one another, it is understood that the terminals, for example terminals A1 and B1, are not short circuited. In other words, the terminals, for example terminals A1 and B1, are coupled by at least one electrical component. For example, the terminals are coupled by at least a transistor, a resistor other than resistors 12 and 12′, an amplifier or any other electrical component not presenting a short circuit connection. For example, each terminal is coupled to a source circuit generating a biasing voltage. The source circuits coupled to the terminals are preferably distinct. The source circuits coupled to terminals A1 and B1 are preferably independent from one another. The terminals are therefore configured to receive distinct voltages. These distinct voltages can, in some operating modes, have the same value, in which case the value k is equal to zero.

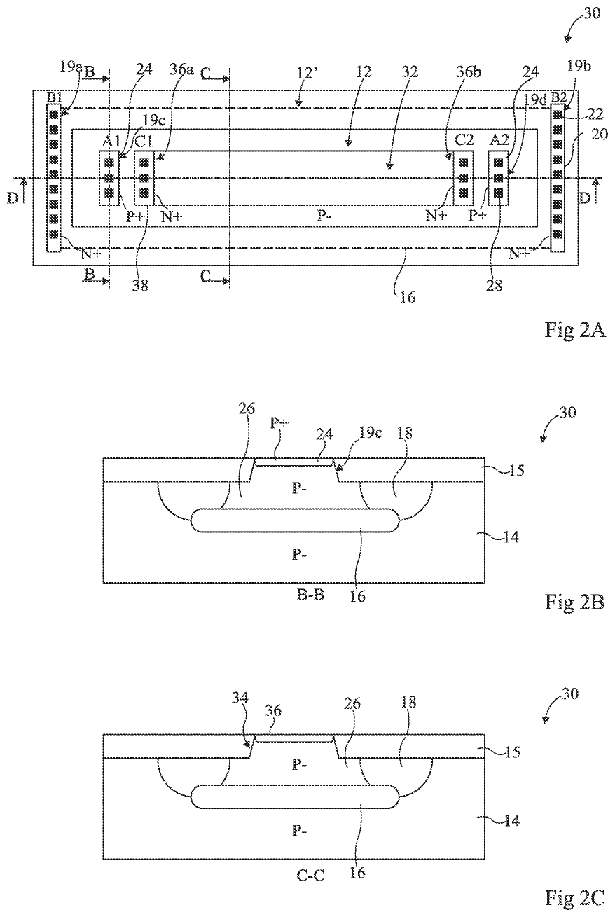

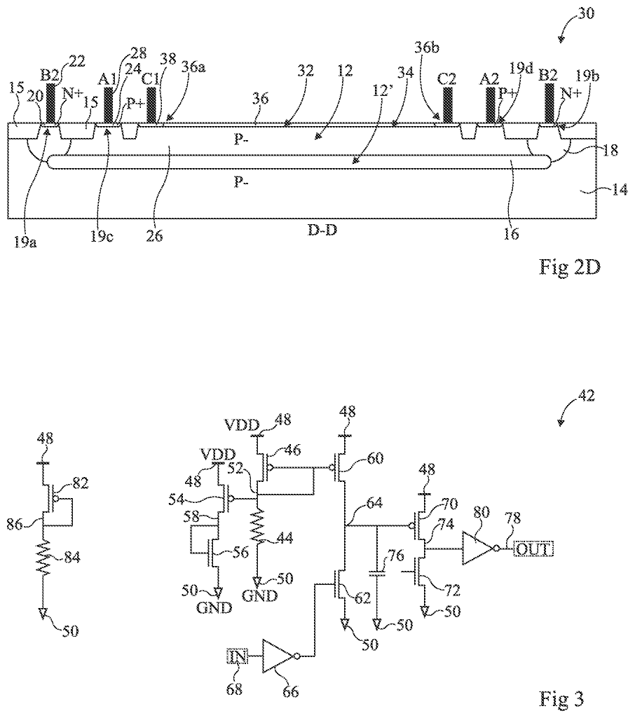

An advantage of biasing resistors 12 and 12′ as previously described is that this makes the resistance value independent from the voltages applied to each of its terminals. In particular, this avoids thickness variations of the space charge area, that is, an area which is emptied of the majority carriers and does not take part in the conduction of the resistor. In usual diffused resistors, the larger the difference between voltage VAP and voltage VBP at a given point P of the interface between resistors 12 and 12′, the more extensive the space charge area, which increases the resistance value. Such a dependency on the voltages applied to each of the terminals is particularly a problem when the resistor is used as a sensor, for example a temperature sensor. This space charge area does not appear in FIGS. 1A to 1C and 2A to 2D.

FIG. 2A is a top view of another embodiment of a device 30 having another diffused resistor 32 formed therein. FIG. 2B is a cross-section view of the embodiment of FIG. 2A along line B-B of FIG. 2A. FIG. 2C is a cross-section view along line C-C of FIG. 2A. FIG. 2D is a cross-section view along a plane D-D of FIG. 2A.

Device 30 comprises elements of device 10 which will not be described again. In particular, device 30 comprises: substrate 14; layer 15, comprising openings 19a, 19b, 19c, and 19d; resistor 12′, that is, layer 16, well 18, and regions 20; and resistor 12, that is, region 26 and regions 24.

Device 30 further comprises resistor 32 formed by N-type diffusion in bar 12 from the front surface, of a strip or region 36, to obtain a rectangle surrounded (on the sides and below) with region 26. Layer 15 then comprises an opening 34 located between openings 19c and 19d. Opening 34 is separated from each of openings 19c and 19d by a portion of layer 15. Opening 34 is separated from each of openings 19a and 19b by portions of layer 15 and opening 19c or 19d. Strip 36 is flush with the upper surface of substrate 14, in opening 34.

Strip 36 has, for example, a cuboid shape. Thus, in the top view of FIG. 2A, strip 36 for example has a rectangle shape. Strip 36 has a first end 36a and a second end 36b. First and second ends 36a, 36b preferably correspond to the two opposite sides most distant from each other of strip 36. Regions 38 at the level of these ends 36a, 36b have the same N conductivity type and define contacting areas 40 intended to be coupled to an electronic circuit. The region 38 located at the level of end 36a forms a terminal C1 of resistor 32. The region 38 located at the level of end 36b forms a terminal C2 of resistor 32. Preferably, strip 36 is not silicided outside of regions 38. Regions 38 are, for example, silicided.

The value of resistor 32 corresponds to the resistance between terminals C1 and C2.

Reference VC refers to a voltage across resistor 32, that is, a potential difference VC1−VC2 between terminals C1 and C2, and reference VA refers to a voltage applied across resistor 12, that is, a potential difference VA1−VA2 between terminals A1 and A2. The device is configured so that the PN junction formed between resistors 12 and 32 is reverse biased. In other words, at each contact point P between resistor 12 and resistor 32, potential VCP, that is, the potential of resistor 32 at point P, is greater than potential VAP, that is, the potential of resistor 12 at point P. Thus, the potential on terminal C1 is preferably higher than the voltage on terminal A1. Similarly, the potential on terminal C2 is preferably higher than the potential on terminal A2. By reverse biased, this would also include the case where the PN junction is zero-biased (in other words, the case where the difference in potential is substantially equal to zero).

The device is further configured so that the difference between the potential of resistor 32 and the potential of resistor 12 is constant across the entire interface between resistors 12 and 32 in the X direction. In other words, at any point P of the interface between resistor 12 and resistor 32, the difference between the potential VAP of resistor 12 and the potential VCP of resistor 32 is substantially equal to a constant value k. Thus, the device is configured so that the following equation applies in the X direction across the entire interface between resistor 12 and resistor 32: VAP−VCP=k. Value k is a constant, positive, or zero value independent from voltage values VA and VC.

For example, value k is strictly a constant, strictly positive, value, and may comprise a value substantially equal to zero. Thus, at any point P of the interface between resistor 12 and resistor 32, the potential VAP of resistor 12 and the potential VCP of resistor 32 are substantially equal.

The device is configured so that the junction between resistors 12 and 12′ is not forward-biased. The device is, for example, configured so that the junction between resistors 12 and 12′ is reverse-biased. For example, potentials VB1 and VB2 are equal to each other and to the maximum value between potentials VA1 and VA2.

FIG. 3 shows an example of a circuit comprising a diffused resistor. More precisely, FIG. 3 shows a delay generation circuit 42 comprising a diffused resistor 44.

Resistor 44 corresponds, for example, to the resistor 12 of FIGS. 1A to 1C or to the resistor 32 of FIGS. 2A to 2D.

Device 42 comprises a transistor 46. Transistor 46 is, for example, an insulated-gate field-effect or MOSFET transistor. Transistor 46 is, for example, a P-channel transistor.

Transistor 46 is series-coupled with resistor 44. Transistor 46 and resistor 44 are series-coupled between a node 48 of application of a power supply voltage VDD and a node 50 of application of a reference voltage, for example ground GND. Transistor 46 is coupled between node 48 and a node 52. The resistor is coupled between node 52 and node 50. In other words, a conduction terminal of transistor 46, for example the source, is coupled, preferably connected, to node 48. Another conduction terminal of transistor 46, for example the drain, is coupled, preferably connected, to node 52. A terminal of resistor 44, for example terminal A2 in the case of resistor 12 or terminal C2 in the case of resistor 32, is coupled, preferably connected, to node 52 and another terminal of resistor 44, for example terminal A1 in the case of resistor 12 or terminal C1 in the case of resistor 32, is coupled, preferably connected, to node 50.

Transistor 46 is diode-mounted. In other words, the control terminal of transistor 46, for example the gate, is coupled, preferably connected, to the drain of transistor 46, that is, for example coupled, preferably connected, to node 52.

Circuit 42 further comprises a transistor 54 and a transistor 56. Transistor 54 is, for example, an insulated-gate field-effect or MOSFET transistor. Transistor 54 is, for example, a P-channel transistor. Transistor 56 is, for example, an insulated-gate field-effect or MOSFET transistor. Transistor 56 is, for example, an N-channel transistor.

Transistors 54 and 56 are series-coupled between node 48 and node 50. More precisely, transistor 54 is coupled between node 48 and a node 58 and transistor 56 is coupled between node 58 and node 50. In other words, a conduction terminal of transistor 54, for example the source, is coupled, preferably connected, to node 48. Another conduction terminal of transistor 54, for example the drain, is coupled, preferably connected, to node 58. Further, a conduction terminal of transistor 56, for example the drain, is coupled, preferably connected, to node 58. Another conduction terminal of transistor 56, for example, the source, is coupled, preferably connected, to node 50. Transistor 54 is coupled in such a way as to conduct a copy of the current flowing through transistor 46.

Transistor 56 is diode-mounted. In other words, the control terminal of transistor 56, for example the gate, is coupled, preferably connected, to the drain of transistor 56, that is, for example coupled, preferably connected, to node 58. Further, the control terminal of transistor 54, for example the gate, is coupled, preferably connected, to node 52.

Circuit 42 further comprises a transistor 60 and a transistor 62. Transistor 60 is, for example, an insulated-gate field effect or MOSFET transistor. Transistor 60 is, for example, a P-channel transistor. Transistor 62 is, for example, an insulated-gate field effect or MOSFET transistor. Transistor 62 is, for example, an N-channel transistor.

Transistors 60 and 62 are series-coupled between node 48 and node 50. More precisely, transistor 60 is coupled between node 48 and a node 64 and transistor 62 is coupled between node 64 and node 50. In other words, a conduction terminal of transistor 60, for example the source, is coupled, preferably connected, to node 48. Another conduction terminal of transistor 60 for example the drain, is coupled, preferably connected, to node 64. Further, a conduction terminal of transistor 62, for example the drain, is coupled, preferably connected, to node 64. Another conduction terminal of transistor 62, for example the source, is coupled, preferably connected, to node 50.

A control terminal of transistor 60, for example the gate, is coupled, preferably connected, to node 52. A control terminal of transistor 62 is coupled, preferably connected, to an output of an inverter 66. An input of inverter 66 is coupled, preferably connected, to an input node 68. An input signal IN is applied to node 68. Transistor 60 is coupled in such a way as to conduct a copy of the current flowing through transistor 46.

Circuit 42 further comprises a transistor 70 and a transistor 72. Transistor 70 is, for example, an insulated-gate field effect or MOSFET transistor. Transistor 70 is, for example, a P-channel transistor. Transistor 72 is, for example, an insulated-gate field effect or MOSFET transistor. Transistor 72 is, for example, an N-channel transistor.

Transistors 70 and 72 are series-coupled between node 48 and node 50. More precisely, transistor 70 is coupled between node 48 and a node 74 and transistor 72 is coupled between node 74 and node 50. In other words, a conduction terminal of transistor 70, for example the source, is coupled, preferably connected, to node 48. Another conduction terminal of transistor 70 for example the drain, is coupled, preferably connected, to node 74. Further, a conduction terminal of transistor 72, for example the drain, is coupled, preferably connected, to node 74. Another conduction terminal of transistor 72, for example the source, is coupled, preferably connected, to node 50.

A control terminal of transistor 70, for example the gate, is coupled, preferably connected, to node 64. Transistor 72 is coupled in such a way as to conduct a copy of the current crossing transistor 56.

Circuit 42 comprises a capacitor 76. Capacitor 76 is coupled between node 64 and node 50. In other words, a terminal du capacitor 76 is coupled, preferably connected, to node 64 and another terminal of capacitor 76 is coupled, preferably connected, to node 50.

Node 74 is coupled to an output node 78, on which is generated, by circuit 42, an output signal OUT. Output signal OUT corresponds to input signal IN to which a delay has been applied. Node 74 is coupled to node 78 by an inverter 80. In other words, an input terminal of inverter 80 is coupled, preferably connected, to node 74 and an output terminal of inverter 80 is coupled, preferably connected, to node 78.

Circuit 42 further comprises a transistor 82 and a resistor 84. Resistor 84 is a diffused resistor. Resistor 84 corresponds to resistor 12′ in the case of the embodiment of FIGS. 1A to 1C or to resistor 12 in the embodiment of FIGS. 2A to 2D. Transistor 82 is, for example, an insulated-gate field effect or MOSFET transistor. Transistor 82 is, for example, a P-channel transistor.

Transistor 82 and resistor 84 are series-coupled between node 48 and node 50. More precisely, transistor 82 is coupled between node 48 and a node 86. Resistor 84 is coupled between node 86 and node 50. In other words, a conduction terminal of transistor 82, for example the source, is coupled, preferably connected, to node 48 and another conduction terminal of transistor 82, for example the drain, is coupled, preferably connected, to node 86. A terminal of resistor 84, for example terminal B2 in the case of the resistor 12′ of FIGS. 1A to 1C or terminal A2 in the case of the resistor 12 of the embodiment of FIGS. 2A to 2D, is coupled, preferably connected, to node 86 and another terminal of resistor 84, for example terminal B1 in the case of the resistor 12′ of FIGS. 1A to 1C or terminal A1 in the case of the resistor 12 of the embodiment of FIGS. 2A to 2D, is coupled, preferably connected, to node 50.

Transistor 82 is diode-mounted. In other words, the control terminal of transistor 82, for example the gate, is coupled, preferably connected, to the drain of transistor 82, that is, for example coupled, preferably connected, to node 58.

The size of transistor 82, that is, the width-to-length ratio of the channel, is configured so that the voltage across resistor 84 is substantially equal to the voltage across resistor 44. In other words, the size of transistor 82 is configured so that the potential difference between the terminals of resistor 84 is substantially equal to the potential difference between the terminals of resistor 44. For example, the size of the transistor is equal to the size of transistor 46 multiplied by the quotient Q of the resistance value or resistor 44 to the resistance value of resistor 84. For example, transistor 46 is formed of one or a plurality of elementary transistors, the elementary transistors being identical. Transistor 82 is then formed of Q times more identical elementary transistors than transistor 46.

Delay generation circuit 42 is configured to apply a delay T to a signal. In other words, when signal IN takes a value at a time t, for example a binary value ‘1’, output signal OUT takes said value at a time t+T.

During the operation of the circuit, the current flowing through transistor 46 is equal to (VDD−VtP)/R, VtP corresponding to the threshold voltage of transistor 46 and R corresponding to the value of resistor 44. The current flowing through transistor 60 is proportional to the current flowing through transistor 46 with a ratio of 1/n, n being a positive integer, transistors 46 and 60 being assembled as a current mirror.

If input signal IN has a low value, that is, a value corresponding to binary value ‘0’, transistor 62 is conducting, and capacitor 76 discharges via transistor 62, the current flowing through transistor 62 being more significant than the current flowing through transistor 60.

If input signal IN has a high value, that is, a value corresponding to binary value ‘l’, transistor 62 is non-conductive. Capacitor 76 is thus charged via transistor 60. The voltage V across capacitor 76 complies with the following equation V(t)=t*(VDD−VtP)/(n*R*C), C being the capacitance value of capacitor 76.

At the beginning of the charge of capacitor 76, voltage V is smaller than VDD−VtP, transistor 70 is thus conducting and output signal OUT has binary value ‘0’. When V reaches value VDD−VtP, that is, when t=T=n*R*C, transistor 70 becomes non-conductive and output signal OUT takes binary value ‘1’.

In the example of FIG. 3, circuit 42 is configured so that the potentials on terminals A1 and B1 are equal to each other and to voltage VDD−VtP and that the potentials on terminals A2 and B2 are equal to each other and to a zero voltage. For this purpose, terminals A2 and B2 are both coupled to node 50. To ascertain that the potentials on terminals A1 and B1 are equal, the current densities flowing through transistors 82 and 46 have to be identical. More precisely, if transistors 46 and 82 each correspond to a plurality of elementary transistors identical to one another, the current density in each of the elementary transistors has to be the same. The potential difference between resistor 44 and resistor 84, which corresponds to the well having resistor 44 formed therein, is thus constant and zero at any point of the interface between resistors 44 and 84.

An advantage of using a resistor according to the described embodiments is that this makes the generated delay independent from variations of the voltage applied across the resistor, and thus independent from the power supply voltage.

More generally, an embodiment of a circuit for biasing diffused resistors such as those described in relation with FIGS. 1A to 2D comprises a resistor such as the resistor 12 of the embodiment of FIGS. 1A to 1C or as the resistor 32 of the embodiments of FIGS. 2A to 2D series-coupled with a diode-mounted transistor, such as transistor 46, and a resistor such as the resistor 12′ of the embodiment of FIGS. 1A to 1C or as the resistor 12 of the embodiments of FIGS. 2A to 2D series-coupled with a diode-mounted transistor, such as transistor 82.

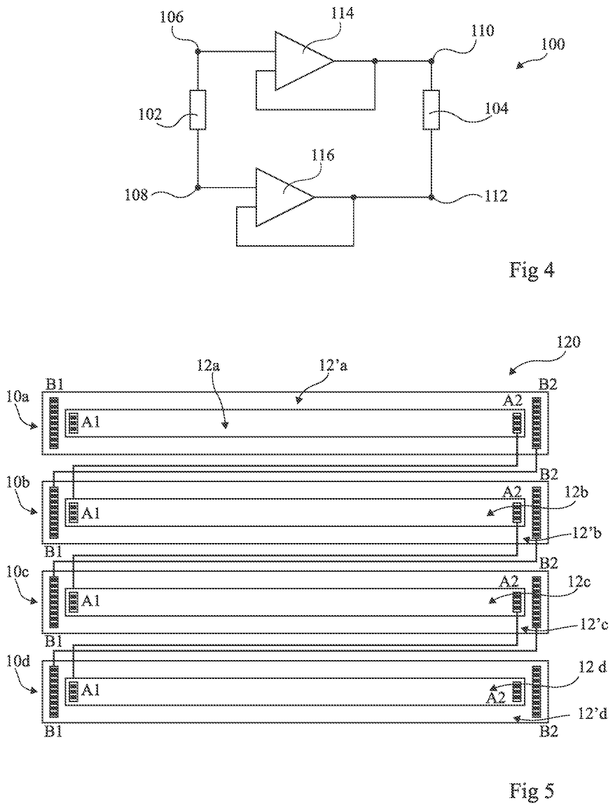

FIG. 4 shows another circuit comprising a diffused resistor. More precisely, FIG. 4 shows a circuit enabling to ascertain that the voltages of the diffused resistors are such as previously described.

Circuit 100 comprises diffused resistors 102 and 104. Resistor 102 corresponds, for example, to the resistor 12 of FIGS. 1A to 1C or to the resistor 32 of FIGS. 2A to 2D. Resistor 104 corresponds, for example, to resistor 12′ in the case of the embodiment of FIGS. 1A to 1C or to resistor 12 in the embodiment of FIGS. 2A to 2D. Resistor 102 comprises a terminal 106, corresponding to the terminal A1 of the resistor 12 of FIGS. 1A to 1C or to the terminal C1 of the resistor 32 of FIGS. 2A to 2D, and a terminal 108, corresponding to the terminal A2 of the resistor 12 of FIGS. 1A to 1C or to the terminal C2 of the resistor 32 of FIGS. 2A to 2D. Resistor 104 comprises a terminal 110, corresponding to the terminal B1 of resistor 12′ in the case of the embodiment of FIGS. 1A to 1C or to the terminal A1 of resistor 12 in the embodiment of FIGS. 2A to 2D, and a terminal 112 corresponding to the terminal B2 of resistor 12′ in the case of the embodiment of FIGS. 1A to 1C or to the terminal A2 of resistor 12 in the embodiment of FIGS. 2A to 2D.

Terminal 106 is coupled to terminal 110 by a voltage follower circuit. Similarly, terminal 108 is coupled to terminal 112 by a voltage follower circuit.

In the example of FIG. 4, each follower circuit comprises an operational amplifier. More precisely, terminals 106 and 110 are coupled by an operational amplifier 114 and terminals 108 and 112 are coupled by an operational amplifier 116. Amplifier 114 comprises an output coupled, preferably connected, to terminal 110. Amplifier 114 comprises an input coupled, preferably connected, to terminal 106. Amplifier 114 comprises another input coupled, preferably connected, to the output of amplifier 114. Amplifier 116 comprises an output coupled, preferably connected, to terminal 112. Amplifier 116 comprises an input coupled, preferably connected, to terminal 108. Amplifier 116 comprises another input coupled, preferably connected, to the output of amplifier 116.

FIG. 5 shows an application of the previously-described embodiments. More precisely, FIG. 5 shows a device 120 comprising a plurality of devices 10, four devices 10, bearing references 10a, 10b, 10c, and 10d, being shown in FIG. 5.

Each device 10a, 10b, 10c, 10d is such as described in relation with FIGS. 1A to 1C. Each device 10a, 10b, 10c, and 10d comprises a resistor 12 and a resistor 12′. More precisely, devices 10a, 10b, 10c, and 10d respectively comprise a resistor 12a, 12b, 12c, or 12d and a resistor 12′a, 12′b, 12′c, or 12′d. Each resistor 12a, 12b, 12c, or 12d comprises terminals A1 and A2. Similarly, each resistor 12′a, 12′b, 12′c, or 12′d comprises terminals B1 and B2.

Devices 10a, 10b, 10c, and 10 are coupled in series. More precisely, resistors 12a, 12b, 12c, or 12d are coupled in series to form a resistor of greater value. For example, the terminal A2 of resistor 12a is coupled, preferably connected, to the terminal A1 of resistor 12b, the terminal A2 of resistor 12b is coupled, preferably connected, to the terminal A1 of resistor 12c, the terminal A2 of resistor 12c is coupled, preferably connected, to the terminal A1 of resistor 12d.

Further, resistors 12′ are series-coupled in the same way as resistors 12. In other words, for each terminal of a resistor 12 coupled, preferably connected, to a terminal of another resistor 12, the terminals B1, B2 of resistors 12, closest to said terminals of resistors 12 are coupled, preferably connected, to one another. Thus, the terminal B2 of resistor 12′a is coupled, preferably connected, to the terminal B1 of resistor 12′b, the terminal B2 of resistor 12′b is coupled, preferably connected, to the terminal B1 of resistor 12′c, the terminal B2 of resistor 12′c is coupled, preferably connected, to the terminal B1 of resistor 12′d.

The coupling of the resistors enables to ensure the constancy of the potential difference between each resistor 12 and the associated resistor 12′. Device 120 thus comprises, between the terminal A1 of resistor 12a and the terminal A2 of resistor 12d, a resistor equivalent to the sum of the resistance values of the four resistors 12.

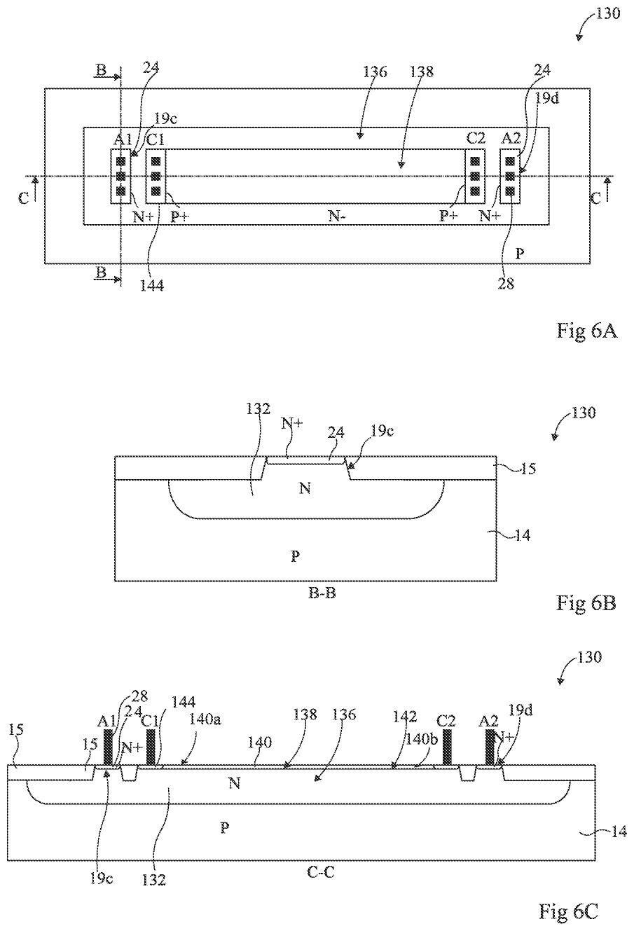

FIG. 6A is a top view of another embodiment of a device 130 comprising a diffused resistor. FIG. 6B is a cross-section view, along a line B-B, of the embodiment of FIG. 6A. FIG. 6C is a cross-section view, along a line C-C, of an embodiment of FIG. 6A.

Device 130 comprises elements of the device 10 of FIGS. 1A to 1C which will not be described again in detail. Device 130 comprises: substrate 14, P-type doped; layer 15 comprising openings 19c, 19d; regions 24 in openings 19c and 19d; and contacts 28.

Device 130 comprises a well 132 in substrate 14. Well 132 is on the front surface side of substrate 14. Well 132 is of the second conductivity type (N). Well 132 forms a resistive bar. Well 132 extends at least from region 24 in opening 19c to region 24 in opening 19d. Well 132 is in contact with said regions 24. Regions 24 and well 132 form a diffused resistor 136.

Device 130 further comprises a resistor 138, similar to the resistor 32 of FIGS. 2A to 2D, formed by the P-type diffusion in well 132 from the front surface, of a strip or region 140, to obtain a rectangle surrounded (on the sides and below) by well 132. Layer 15 then comprises an opening 142 located between openings 19c and 19d. Opening 142 is separated from each of openings 19c and 19d by a portion of layer 15. Strip 140 is flush with the upper surface of substrate 14, in opening 142.

Strip 140 is flush with the front surface of substrate 14. Strip 140 for example has a cuboid shape. Thus, in the top view of FIG. 6A, strip 140 has, for example, a rectangle shape. Strip 140 has a first end 140a and a second end 140b. The first and second ends 140a, 140b preferably correspond to the two opposite sides most distant from each other of strip 140. Regions 144 at the level of these ends 140a, 140b have the same P conductivity type and define contacting areas intended to be coupled to an electronic circuit. The region 144 located at the level of end 140a forms a terminal C1 of resistor 138. The region 144 located at the level of end 140b forms a terminal C2 of resistor 138. Preferably, strip 140 is not silicided outside of regions 144. Regions 144 are, for example, silicided.

The value of resistor 138 corresponds to the resistance between terminals C1 and C2.

The resistors 136 and 138 of FIGS. 6A to 6C are, for example, configured to be biased in the same way as the resistors 12′ and 12, respectively, of the device 10 of FIGS. 1A to 1C.

An advantage of the described embodiments is that the value of the diffused resistor is not dependent on the value of the voltages at each of the terminals of the resistor, and thus of the power supply voltage.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An electronic device, comprising:
a first diffused resistor; and
a second diffused resistor;
wherein the first and second diffused resistors are in contact with each other to form a PN junction;
wherein the PN junction is reverse-biased; and
wherein a potential difference between the first and second resistors is constant at any point of the PN junction.

2. The device according to claim 1, wherein each of the first and second diffused resistors is made of a doped semiconductor material, the first and second diffused resistors being doped with opposite conductivity types.

3. The device according to claim 1, wherein:
the first diffused resistor comprises a first layer buried in a substrate and a first well, the first well extending from a periphery of the first layer to a first surface of the substrate, the first layer and the first well being made of a doped semiconductor material of a first conductivity type; and
the second resistor comprises a second layer resting on the first layer, the second layer being made of a doped semiconductor material of a second conductivity type opposite the first conductivity type.

4. The device according to claim 1, wherein:
the second diffused resistor comprises a third doped semiconductor layer of a first conductivity type, the third doped semiconductor layer being flush with an upper surface of a substrate; and
the first resistor comprises a second layer made of a doped semiconductor material of a second conductivity type opposite the first conductivity type, the third doped semiconductor layer resting on the second layer.

5. The device according to claim 4, further comprising a third diffused resistor comprising a first layer buried in the substrate and a first well, the first well extending from a periphery of the first layer to the first surface of the substrate, the first layer and the first well being made of a doped semiconductor material of the first conductivity type, the first layer and the first well delimiting the second layer.

6. The device according to claim 5, wherein the PN junction between the first and the third resistor is configured to be reverse-biased.

7. The device according to claim 1, wherein:
the first diffused resistor comprises a semiconductor well in a substrate, the semiconductor well being doped with a doping type opposite to a doping type of the substrate; and
the second diffused resistor comprises a third doped semiconductor layer of the doping type opposite to the doping type of the semiconductor well, the third doped semiconductor layer being flush with an upper surface of the substrate.

8. The device according to claim 1, wherein each of the diffused resistors comprises a first end and a second end, each diffused resistor comprising, at a level of the first and second ends, a semiconductor region that is more heavily doped than a rest of the diffused resistor which forms a terminal of said diffused resistor.

9. The device according to claim 1, wherein each first and second diffused resistor comprises first and second terminals, the second terminals of the first and second diffused resistors being coupled to a same first node of application of a reference voltage.

10. The device according to claim 1, further comprising a control circuit configured to supply potentials on terminals of the first and second diffused resistors.

11. The device according to claim 10, wherein the control circuit comprises a first transistor series-coupled with the first diffused resistor between a second node of application of a power supply voltage and the first node and a second transistor series-coupled with the second diffused resistor between the second node and the first node, the first and second transistors being diode-mounted.

12. The device according to claim 11, wherein the first transistor has a channel width-to-length ratio equal to a channel width-to-length ratio of the second transistor multiplied by a quotient of a value of a second resistance for the second diffused resistor to a value of a first resistance for the first diffused resistor.

13. The device according to claim 1, wherein the device is configured so that the potential difference between the first and second resistors is zero at any point of the PN junction.

14. A sensor, comprising:
a device according to claim 1, the sensor being configured so that a measurement value of the sensor is dependent on a resistance value of one of the first and second diffused resistors.

15. A device, comprising:
a first region of doped semiconductor material of a first conductivity type;
a second region of doped semiconductor material of a second conductivity type opposite the first conductivity type;
a first electrical contact at a first end of the first region;
a second electrical contact at a second end of the first region;
wherein the first region forms a first diffused resistor between the first and second electrical contacts;
a third electrical contact at a first end of the second region;
a fourth electrical contact at a second end of the second region;
wherein the second region forms a second diffused resistor between the third and fourth electrical contacts;
wherein the first region is in contact with the second region to form a PN junction;
wherein a first voltage difference is applied between the first and second terminals;
wherein a second voltage difference is applied between the third and fourth terminals; and
wherein the first and second voltage differences are configured such that the PN is reverse biased.

16. The device according to claim 15, further comprising a control circuit configured to supply first voltage difference between the first and second terminals and to supply the second voltage difference between the third and fourth terminals.

17. The device according to claim 15, further comprising:
a first transistor series-coupled with the first diffused resistor between a power supply voltage and the first terminal; and
a second transistor series-coupled with the second diffused resistor the power supply node and the third terminal.

18. The device according to claim 17, wherein the first and second transistors are each a diode-connected transistor.

19. The device according to claim 17, wherein the first transistor has a first channel width-to-length ratio and the second transistor has a second channel width-to-length ratio different from the first channel width-to-length ratio.

20. The device according to claim 19, wherein a difference between the first and second channel width-to-length ratios is a function of a quotient of a resistance of the second diffused resistor to a resistance of the first diffused resistor.

21. A sensor, comprising:
a device according to claim 15, the sensor being configured so that a measurement value of the sensor is dependent on a resistance value of one of the first and second diffused resistors.
